(19) United States
(12) Patent Application Publication
(10) Pub. No.: US 2025/0299984 A1
(43) Pub. Date: Sep. 25, 2025

(54) DIE AND CARRIER REMOVAL TOOL AND METHOD OF UTILIZING THE SAME

(71) Applicant: Taiwan Semiconductor Manufacturing Co., Ltd., Hsinchu (TW)

(72) Inventors: Szu-Hsien LEE, Hsinchu (TW); Chia Hsiu LI, Hsinchu (TW); Shao-Yu WU, Hsinchu (TW); Pei-Wei LEE, Hsinchu (TW); Ming-Da CHENG, Hsinchu (TW)

(21) Appl. No.: 18/611,057

(22) Filed: Mar. 20, 2024

(51) Int. Cl. H01L 21/67; B32B 43/00; H01L 21/683; H01L 21/78

(52) U.S. Cl. CPC H01L 21/67132; B32B 43/006; H01L 21/6836; H01L 21/78

(57) ABSTRACT

A tool is configured to, in operation, remove one or more semiconductor die or packages from a carrier, which may be a tape including an adhesive. The tool includes a shelf structure that includes a first side and a second side opposite to the first side. The shelf structure further includes a first shelf portion and a second shelf portion that are separated from each other by a gap. In operation, the carrier passes along a carrier pathway and the gap is along the carrier pathway such that the carrier passes through the gap. A first roller on the first side of the shelf structure freely rotates in operation guiding the carrier along the carrier pathway, and a second roller on the second side of the shelf structure is driven in operation to guide the carrier along the carrier pathway through the gap.

### BACKGROUND

Semiconductor dice or semiconductor packages are manufactured by applying a carrier or support to a stacked structure. For example, the stacked structure may include a substrate on which one or more non-conductive layers and one or more conductive layers are stacked. These one or more non-conductive and conductive layers are formed on the substrate to form one or more functional or electrical structures of the semiconductor dice or semiconductor packages. At some point during the manufacturing process, the substrate of the stacked structure is coupled to the carrier or support, which may be a non-ultraviolet (non-UV) tape including an adhesive. After the substrate of the stacked structure is coupled to the non-UV tape, the stacked structure may be further processed or refined to manufacture the semiconductor dice or semiconductor packages. At some point in time in forming the semiconductor dice or packages, the non-UV tape is removed from the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top plan view of one or more semiconductor die or packages coupled to a carrier or a support material, which may be a tape.

FIG. 2A is a perspective view of a tool configured to, in operation, remove one or more semiconductor die from a carrier or support, in accordance with some embodiments.

FIG. 2B is a side view of the tool as shown in FIG. 2A configured to, in operation, remove the one or more semiconductor die from the carrier or support, in accordance with some embodiments.

FIG. 2C is a zoomed in, enhanced view of section 2C-2C as shown in FIG. 2B of the tool as shown in FIGS. 2A and 2B configured to, in operation, remove the one or more semiconductor die from the carrier or support, in accordance with some embodiments.

FIG. 3 is a flowchart of a method of utilizing the tool as shown in FIGS. 2A-2C configured to, in operation, remove the one or more semiconductor die from the carrier or support, in accordance with some embodiments.

FIG. 4A is a perspective view of the tool as shown in FIGS. 2A-2C in operation to remove the one or more semiconductor die from the carrier or support.

FIG. 4B is a cross-sectional, side view of the tool as shown in FIGS. 2A-2C in operation to remove the one or more semiconductor die from the carrier or support.

FIG. 4C is a zoomed-in, enhanced view of the section 4C-4C as shown in FIG. 4B of the tool as shown in FIGS. 2A-2C in operation to remove the one or more semiconductor die from the carrier or support, in accordance with some embodiments.

FIG. 4D is a top plan view of the one or more semiconductor die after in a safety zone of the tool as shown in FIGS. 2A-2C configured to, in operation, remove the one or more semiconductor die from the carrier or support after performing the method of utilizing the tool as shown in FIG. 3, in accordance with some embodiments.

FIG. 5 is a flowchart of a method of manufacturing one or more semiconductor die or packages including a MEMS structure by utilizing an etching process followed by the method of utilizing the tool as shown in FIGS. 1A-1C to remove the one or more semiconductor die from the carrier or support, in accordance with some embodiments.

FIG. 6A is a cross-sectional view of a respective step of the method of manufacturing the MEMS structure and device as shown in the flowchart of FIG. 5.

FIG. 6B is a cross-sectional view of a respective step of the method of manufacturing the MEMS structure and device as shown in the flowchart of FIG. 5.

FIG. 6C is a cross-sectional view of a respective step of the method of manufacturing the MEMS structure and device as shown in flowchart of FIG. 5.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to one or more embodiments of a tool configured to, in operation, remove one or more semiconductor die or packages from a carrier. The semiconductor die or packages may include micro-electromechanical systems (MEMS) that include microscopic components that are susceptible to damage and defects when exposed to relatively large external stresses and strains. The tool is automated to remove the one or more semiconductor die or packages from the carrier to improve efficiency of a semiconductor manufacturing plant (FAB) by increasing the units (e.g., semiconductor die) per hour (UPH) that may be removed from respective carriers. The tool is automated to replace manual removal of the one or more semiconductor die or packages from the carrier by an employee decreasing a number of defects (e.g., remaining adhesive on the one or mores semiconductor die, cracking within the one or more semiconductor die or packages, delamination between layers of the one or mores semiconductor die or packages, or some other similar or like types of defects that may occur due to a manual operation being performed by an employee).

The semiconductor die or packages that include the MEMS may be formed by forming MEMS structures over or on a substrate to form MEMS devices. After the MEMS devices are formed, a front side of the MEMS devices over or on the substrate is coupled to a glue layer of a tape. The glue layer is resistant to a wet etching chemical. Once the MEMS devices are coupled to the glue layer of the tape, a wet etching process is performed on the substrate to separate the MEMS device into individual semiconductor die or packages that each include one or more corresponding ones of the MEMS devices. After being singulated into individual semiconductor die or packages, the semiconductor die or packages are removed utilizing the tool of the present disclosure that is configured to, in operation, remove the one or more semiconductor die or packages from the glue layer of the tape to prevent or reduce the likelihood of residue of the glue layer remaining on the MEMS devices when removed from the glue layer of the tape.

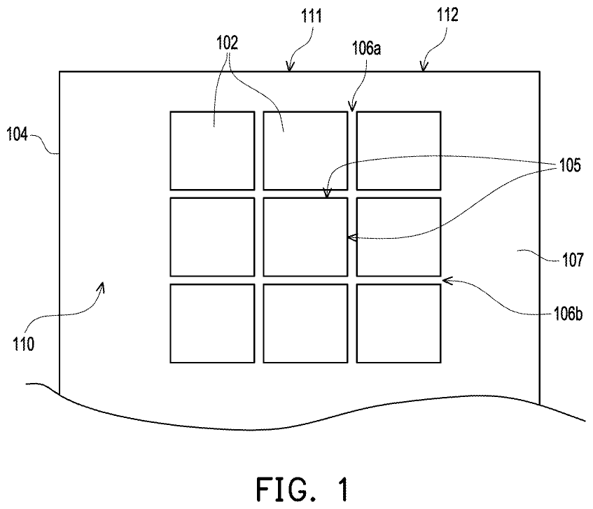

FIG. 1 is a top plan view of one or more semiconductor die or packages coupled to a carrier or a support material, which may be a tape.

In some situations a manual process is utilized to remove one or more semiconductor die, packages, or components 102 from a glue layer of a tape. For example, an employee (i.e., a human being) carries out successive steps of the manual method. This manual method may be performed over and over again (i.e., successively) to remove all of the one or more semiconductor die or packages 102 from a glue layer on a carrier or a support material 104, which may be a tape.

For example, a plurality of semiconductor dies or packages are coupled to the support material 104. In this situation, the support material 104 is a tape including a glue layer or adhesive 107 to which the plurality of semiconductor dies or packages 102 are coupled. The support material 104 includes a first side 110 and a second side 111 opposite to the first side 110. The glue layer or adhesive 107 is on the first side 110 of the support material 104. The support material 104 further includes an end 112 at which support material 104 terminates. The one or more semiconductor die or packages 102 are arranged in an array such that each respective semiconductor die or package is spaced apart from another adjacent respective semiconductor die or package by spaces, gaps, or channels 106a, 106b that are delimited by the support material 104 and respective sidewalls 105 of the one or more semiconductor die or packages 102. The channels 106a, 106b include one or more first channels 106a that extend in a first direction and one or more second channels 106b that extend in a second direction transverse to the first direction. In this situation, the first channels 106a are perpendicular or orthogonal to the second channels 106b as the one or more semiconductor die or packages 102 have a rectangular or square shape and profile.

When the employee manually removes all of the one or more semiconductor die or packages 102 from the glue layer or adhesive on the support material 104, the time it takes to remove all of the one or more semiconductor die or packages 102 from the support material 104 takes a relatively long time (e.g., 5 minutes or more) that results in units per hour (UPH) output by a semiconductor manufacturing or fabrication plant (FAB) being reduced.

When this process is performed manually by the employee in succession to remove the one or more semiconductor die or packages 102 from the support material 104, there is relatively high likelihood that at least one or more of the one or more semiconductor die or packages 102 may be deformed or damaged due to inconsistencies when the employee manually removes the one or more semiconductor die or packages 102 from the support material 104. In some instances, the deformation or damage may be minor such that the deformed or damaged ones of the one or more semiconductor die or packages 102 are still within selected tolerances such that they pass quality control and sold to a customer. However, in some instances, the deformation or damage may be major such that the damaged or deformed semiconductor die or packages 102 are outside of selected tolerances such that they do not pass quality control and instead become waste of the FAB resulting in lost income.

In view of the above discussion, the present disclosure is directed to providing a system or device to remove the one or more semiconductor die or packages 102 from the support material 104 faster to increase UPH of the FAB while at the same time reducing the likelihood of deformation or damage occurring when removing the one or more semiconductor die or packages 102 from the support material 104. Reducing the time it takes to remove all of the one or more semiconductor die and packages 102 from the support material 104 improves the UPH of the FAB as a greater number of the semiconductor die or packages 102 may be manufactured. Similarly, reducing the likelihood of deformation or damage when removing the one or more semiconductor die or packages 102 from the support material 104 improves the UPH of the FAB as a greater number of the semiconductor due or packages 102 pass quality control and are sold to customers.

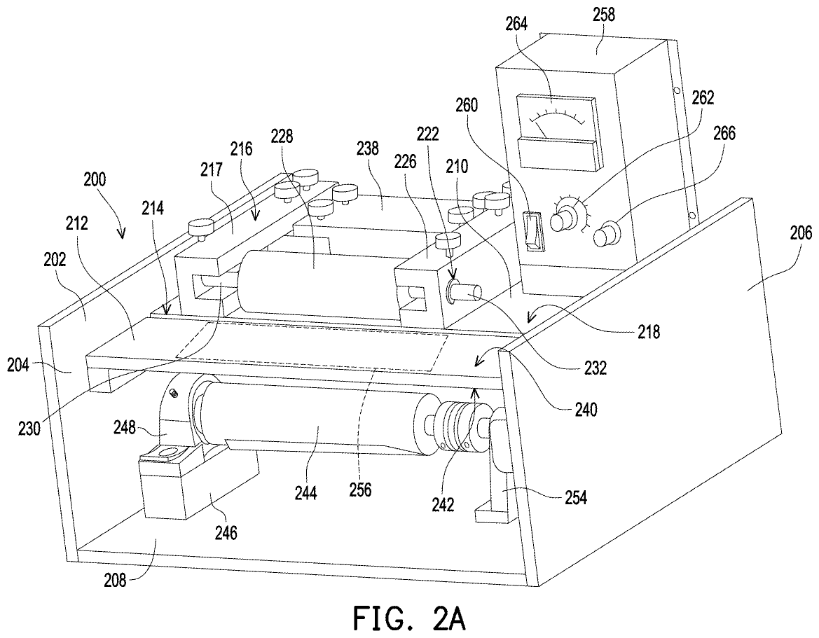

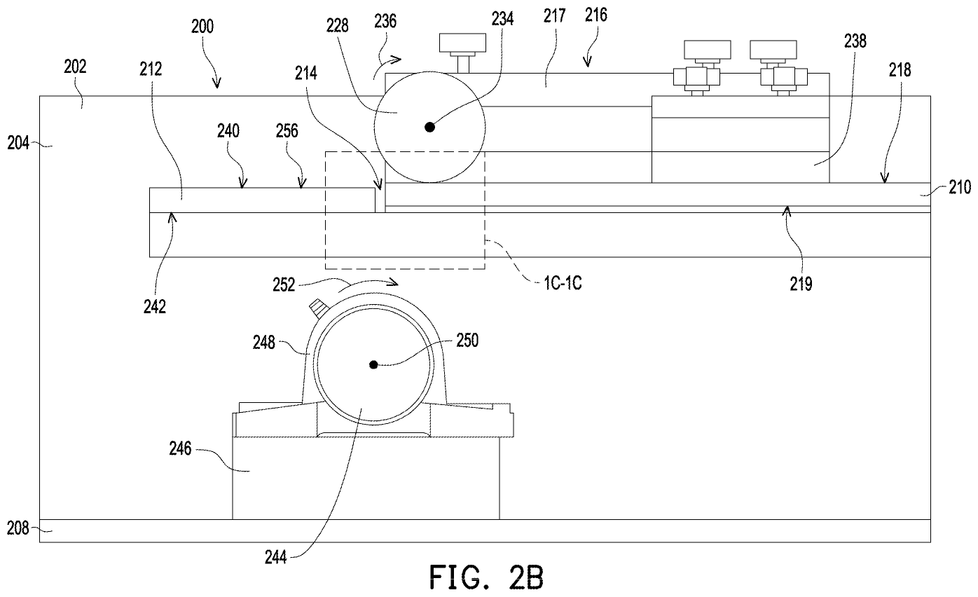

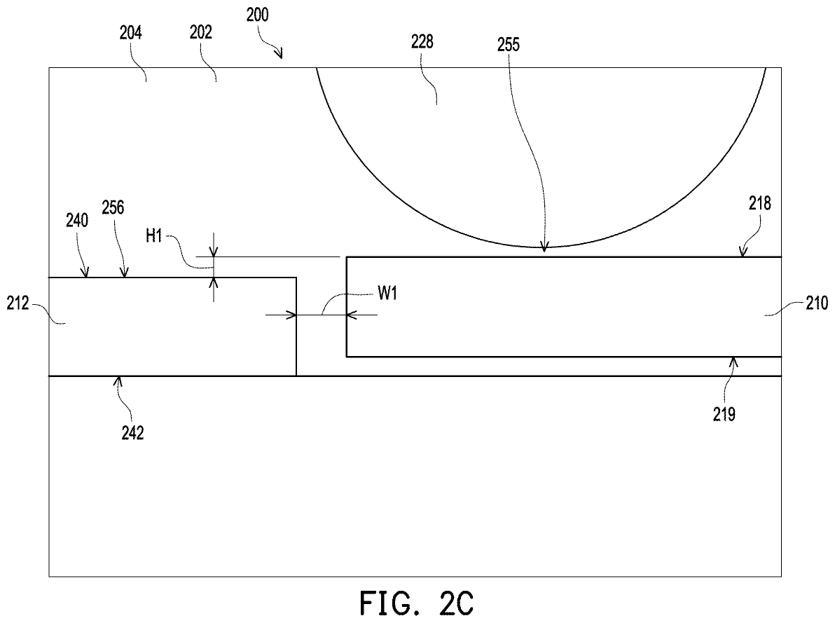

FIG. 2A is directed to a perspective view of a die or package removal tool or device 200. The removal tool 200 includes a structure 202, which may be referred to as a shelf support structure or shelf structure. The shelf structure 202 includes a first sidewall or sidewall portion 204, a second sidewall or sidewall portion 206, and a base or base portion 208. The first sidewall 204 and the second sidewall 206 are coupled together by the base 208. As shown in FIG. 2, the first sidewall 204, the second sidewall 206 and the base 208 have a C-shape channel structure, a U-shape channel structure, or some other similar or like reference to the structure of the shelf structure 202. A first shelf or first shelf portion 210 overlaps the base 208 and extends from the first sidewall 204 to the second sidewall 206. A second shelf or second shelf portion 212 overlaps the base 208 and extends from the first sidewall 204 to the second sidewall 206. In the embodiment as shown in FIG. 2A, the second shelf 212 is fully separated from the first shelf 210 by a gap 214. In the embodiment as shown in FIG. 2A, the gap 214 extends from the first sidewall 204 to the second sidewall 206. In at least one alternative embodiment, the gap 214 may not fully extend from the first sidewall 204 to the second sidewall 206 and the first and second shelf portions may be a single shelf portion of which a slot that replaces the gap 214 extends.

A support structure 216 extends outward from a first side 218 of the first shelf 210. The support structure 216 includes a first channel structure 217 and a second channel structure 226. Respective channels of the first and second channel structures 217, 226 face each other as shown in FIG. 2. The second channel structure 226 includes an opening 222 that is aligned with the respective channel in the second channel structure 226. The first shelf 210 includes a second side 219 opposite to the first side 218 (see FIG. 2B of the present disclosure).

A first roller 228 is supported by the support structure 216. The first roller 228 includes a first end 230, which has a shaft-like structure, that is within the respective channel of the first channel structure 217 and a second end 232, which has a shaft-like structure, that is within the respective channel of the second channel structure 226. The second end 232 is inserted into the opening 222 and passes through the opening 222. As shown in FIG. 2A, the first roller has a shape and structure like a rolling pin. The first roller 228 is supported by the first and second channel structures 217, 226 of the support structure 216 such that the first roller 228 is free to rotate about a first rotation axis 234 in a first rotation direction as represented by an arrow 236 (see FIG. 2B of the present disclosure). The first roller 228 overlaps the first shelf 210

A guide structure 238 is supported by the support structure 216. While not readily visible, a space, which is small and not readily visible in FIG. 2A, is present between a lower surface of the guide structure 238 and the first side 218 of the first shelf 210 such that a support material (e.g., a tape) to which one or more dies or packages are coupled may readily pass through. In other words, the guide structure 238 is configured to, in operation of the tool 200, guide the support material (e.g., the tape) to which the one or more dies or packages are coupled move along the first side 218 of the first shelf 210. The guide structure 238 overlaps the first shelf 210.

The second shelf 212 includes a third side 240 and a fourth side 242 opposite to the third side 240. A second roller 244 is overlapped by the second shelf 212. The second roller 244 is between the base 208 and the second shelf 212. Similar to the first roller 228, the second roller 244 has a shape and structure like a rolling pin.

A bearing, driving structure, or motor base 246 extends outward from the base 208 and is between the base 208 and the second shelf 212. A driving structure 248, which may be a motor or some other structure or device to driving rotation of the second roller 244, is coupled to the driving structure base 246. The driving structure 248 includes a bearing that is coupled to an end (not visible) of the second roller 244. The end of the second roller 244 may be a shaft-like structure. The driving structure 248 is configured to, in operation of the tool 200, drive rotation of the second roller about a second rotation axis 250 in a second rotation direction as represented by an arrow 252 (see FIG. 2B of the present disclosure). A second roller support structure 254 provides support to an end of the second roller opposite to the end of the second roller 244 in mechanical cooperation with the driving structure 248.

A safe zone 256 is present along the third side 240 of the second shelf 212. The safe zone 256 is represented by a dotted region as shown in FIG. 2A. In the embodiment of the removal tool 200 as shown in FIG. 2A, the safe zone 256 is spaced inward from the first and second sidewalls 204, 206.

FIG. 2B is a cross-sectional side view of the removal tool 200. The cross-section is taken along a plane that passes through the guide structure 238, the base 208, the first shelf 210, the second shelf 212, the first roller 228, and the second roller 244. As shown in FIG. 2B, the second shelf 212 is slightly offset in a downward direction relative to the first shelf 210 (see FIG. 2C in which this downward offset is more readily visible).

FIG. 2C is a zoomed in, enhanced view of the gap 214 between the first shelf 210 and the second shelf 212. As is more readily visible in FIG. 2C than FIG. 2B, the second shelf 212 is slightly offset in a downward direction relative to the first shelf 210. A space 255 is present between the first roller 228 and the first side 218 of the first shelf 210. In this embodiment and in view to discussion earlier herein, since the first roller is free to rotate about the first rotation axis 234, the first roller 228 is not driven by a motor or driving structure, and, instead, rotates based on a friction forces between and external surface of the first roller 228 and the plurality of packages 102 as the support material 104 and the plurality of packages 102 pass through the space 255.

A first dimension H1, which may be a height H1, extends from the first side 218 of the first shelf 210 to the third side 240 of the second shelf 212. The first dimension H1 may be less than or equal to 0.2 millimeters (mm). The first dimension H1 may be selected or adjusted based on the plurality of dies or packages 102 being removed from the support material 104.

A second dimension W1, which may be a width W1, extends from the first shelf 210 to the second shelf 212. The second dimension W1 is greater than 0 millimeters (mm) and is less than or equal to a maximum dimension (e.g., a width) of the plurality of dies or packages. This results in the plurality of dies or packages 102 not passing or falling through the gap 214 when removing the plurality of dies or packages 102 from the support material 104.

A controller 258, which is a control box in this embodiment, is in electrical communication with the driving structure 248 to control the driving structure 248. The controller 258 includes a on/off switch 260 to turn the driving structure 248 on and off. The controller 258 includes a torque control input 262 that is utilized to control a torque output by the driving structure 248. In this embodiment as shown in FIG. 2A, the torque control input 262 is a turn knob. In some other embodiments, the torque control input 262 may be some other type of input device or structure for controlling the torque of the driving structure 248. A display 264, which may be analog or digital, outputs and displays a torque that is being output by the driving structure 248. The controller 258 includes a fuse 266 that is present as a safety to prevent damage to the driving structure 248, to the removal tool 100, or to the plurality of dies or packages 102 when utilizing the removal tool 100 to remove the plurality of dies or packages 102 from the support material 104.

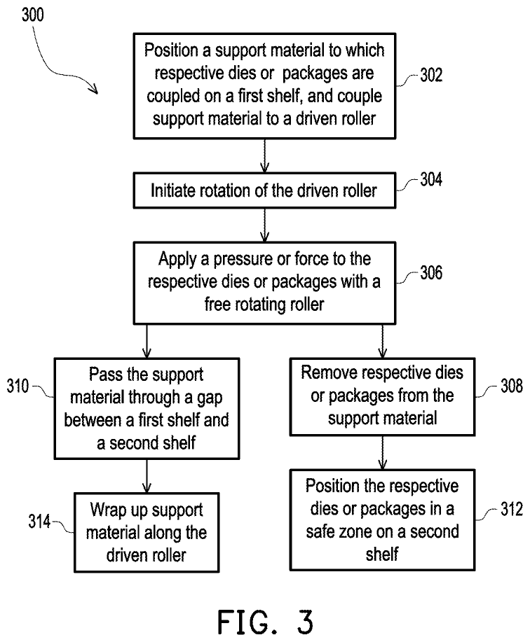

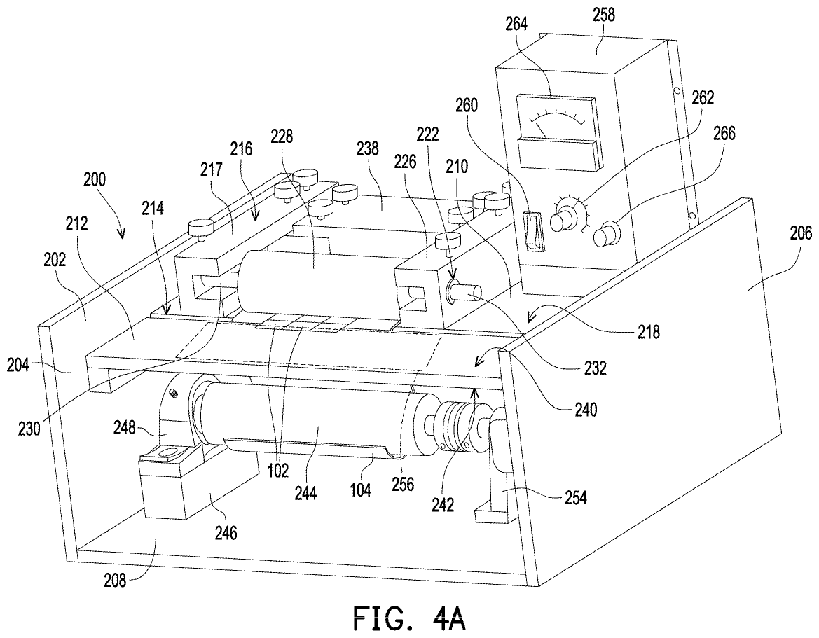

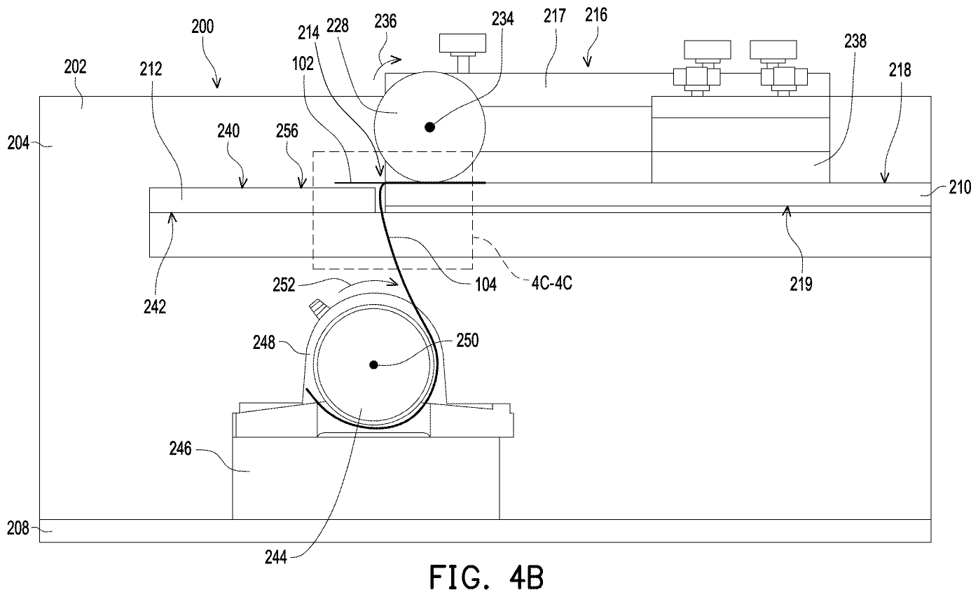

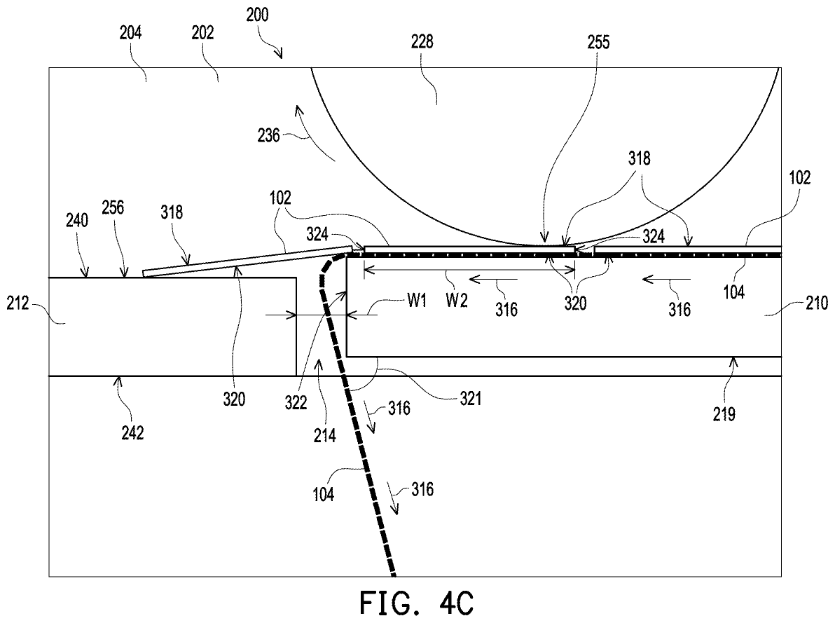

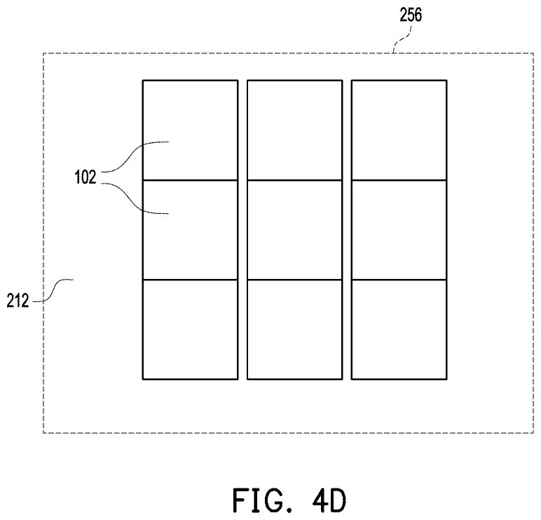

FIG. 3 is directed to a flowchart 300 directed to a method of removing the plurality of dies or packages 102 from the support material 104. The flowchart 300 includes respective steps 302, 304, 306, 308, 310, 312, 314. The details of these respective steps 302, 304, 306, 308, 310, 312, 314 will be discussed in tandem with the details as set forth in FIGS. 4A-4D of the present disclosure, as well as previously described FIGS. 2A-2C of the present disclosure.

In a first step 302, the support material 104 is positioned between the guide structure 238 and the first side 218 of the first shelf 210. The support material 104 is within and passes through the space (not visible) defined between the guide structure 238 and the first side 218 of the first shelf 210. In other words, the support material is sandwiched between the guide structure 238 and the first side 218 of the first shelf 210. The support material 104 is positioned between the first roller 228 and the first side 218 of the first shelf 210. The support material 104 is positioned to pass through the gap 214 between the first shelf 210 and the second shelf 212. The support material 104 includes a respective end that is coupled or adhered (e.g., by the adhesive on the support material 104) to the second roller 244. The plurality of dies or packages 102 coupled or adhered to the support material 104 are positioned somewhere along support material 104 that is upstream from the first roller 228 in a direction opposite to that of a travel direction of the support material 104 when the removal tool 100 is in operation to remove the plurality of dies or packages 102 from the support material 104. The travel direction of the support material 104 is represented by arrows 316 as shown in FIG. 4C, which is directed to an enhanced, zoomed in view similar to FIG. 2B. However, unlike FIG. 2B, the support material 104 is present within the removal tool 100 and is shown in FIG. 4C.

After the first step 302 in which the support material 104 to which the plurality of dies or packages 102 are coupled is positioned within the removal tool 100, in a second step 304 the driving structure 248 is turned on by flipping the on/off switch 260 from an “off” position to an “on” position initiating the driving structure 248. The torque output by the driving structure 248 may be adjusted utilizing the torque control input 262. When the driving structure 248 is turned on, the driving structure 248 being driven by a power supply (not shown) causes the second roller 244 (e.g., driven roller) to rotate in the second rotation direction as represented by the arrow 252 as shown in FIG. 2B. The second roller 244 rotating causes the support material to move in the travel direction as represented by the arrows 316 as shown in FIG. 4C of the present disclosure.

When the removal tool 100 is being utilized to remove the plurality of dies or packages 102 from the support material 104, the driving structure may be outputting a torque within a range of 0.1 N (Newtons) to 0.5 N, or may be outputting a torque equal to the upper and lower ends of this range. In some instances, when the removal tool 100 is being utilized to remove the plurality of dies or packages 102 from the support material 104, the torque output by the driving structure 248 may be less than 0.2 N (Newtons), or the torque output by the driving structure 248 may be equal to 0.2 N.

After the second step 304 in which the driving structure 248 is initiated and turned on to drive rotation of the second roller 244 in the second rotation direction 252, in a third step 306 the plurality of dies or packages 102 begin to pass under the first roller 228 through the space 255 between the first side 218 of the first shelf 210 and the first roller 228. In other words, the support material 104 moving in the travel direction as represented by the arrows 316 causes the plurality of die or packages 102 coupled to the support material 104 to move in the travel direction as represented by the arrows 316. As the plurality of dies or packages 102 move in the travel direction as represented by the arrows 316, respective upper surfaces 318 (e.g., surfaces opposite to the surfaces coupled to the adhesive on the support material 104) of the plurality of dies and packages 102 come into contact with the first roller 228. This contact between the upper surfaces 318 of the plurality of dies or packages 102 and the first roller 228 causes the first roller 228 to rotate in the first rotation direction as represented by the arrow 236 as shown in FIG. 2B and FIG. 4C. This cause the first roller 228 to rotate as the first roller 228 is free to rotate as discussed earlier herein with respect to FIGS. 2A-2C of the present disclosure. This contact between the upper surfaces 318 of the plurality of dies or packages 102 and the first roller 228 causes the first roller 228 to apply a pressure or a force to the upper surfaces 318 of the plurality of dies or packages 102.

The plurality of dies or packages 102 include respective lower surfaces 320 that are opposite to the upper surfaces 318. The respective lower surfaces 320 of the plurality of dies or packages 102 are coupled to the adhesive on the support material 104.

After the third step 306 in which the plurality of dies or packages 102 pass through the space 255 and the respective upper surfaces 318 of the plurality of dies or packages 102 come into contact the first roller 228, in a fourth step 308 the plurality of dies or packages 102 are removed from the support material 104 and in a fifth step 310 the support material 104 passes through the gap 214. The fourth and fifth steps 308, 310 substantially occur simultaneously with each other.

In the fourth step 308 and the fifth step 310, the support material 104 bends around an end sidewall 322 of the first shelf 210. As the support material 104 bends around the end sidewall 322 of the first shelf and a respective die or package of the plurality of dies or packages 102 reaches the end sidewall 322, the first roller 228 is still in contact with a region of the respective upper surface 318 of the respective die or package 102 just reaching the end sidewall 322. As an initial portion of the respective die or package 102 moves past the end sidewall 322, the support material 104 bends around the end sidewall 322 resulting in the support material beginning to peel away from the respective lower surface 320 of the respective die or package 102. As the respective die or package 102 is removed from the support material 104, the respective lower surface 320 of the respective die or package 102 comes into contact with the third side 240 of the second shelf 212 such that the respective die or package 102 does not pass through the gap. A dimension W2 of the plurality of packages or dies 102 between respective opposite ends 324 of the plurality of dies or packages 102 is larger than the second dimension W1 of the gap 214.

In some instances, the respective die or package 102 being removed from the support material comes into contact with the third side 240 of the second shelf 212 when the support material 104 has only been partially removed from the respective lower surface 320 of the respective die or package (e.g., see left-most respective die or package 102 as shown in FIG. 4C). This contact of the respective die or package 102 with the third side 240 of the second shelf 212 before the support material 104 being fully removed from the respective lower surface 320 of the respective die or package 102 further facilitates the respective lower surface 320 of the respective die or package 102 being removed from the support material 104.

As shown in FIG. 4C, the second shelf 212 is slightly downset from the first shelf 210 to facilitate the support material 104 being removed from the respective lower surface 320 of the respective die or package 102 while reducing the likelihood of deformations, defects, or damage to the respective die or package 102 being removed from the support material 104. In other words, the slight downset of the second shelf 212 relative to the first shelf 210 improves reliability of the support material 104 being fully removed from the respective lower surface 320 of the respective package or die 102 while reducing or mitigating any stresses or strains that may result from the support material 104 being removed from the respective lower surface 320 of the respective die or package 102.

As shown in FIG. 4C, the support material 104 is at an angle 321 relative to the second side 219 of the first shelf 210. The angle is less than ninety (90) degrees. The angle 321 being less than ninety degrees results in the tape moving away from the second shelf 212 as the plurality of dies or packages 102 are removed from the support material 104 onto the second shelf 212 within the safe zone 256.

After the fourth step 308 and the fifth step 310 in which the support material 104 passes through the gap 214 and the plurality of dies or packages 102 are removed from the support material 104, in a sixth step 312 the plurality of dies or packages 102 are placed within the safe zone 256 on the second shelf 212 and in a seventh step 314 the support material 104 is wrapped up on the second roller 244. The sixth and seventh steps 312, 314 substantially occur simultaneously with each other.

In the sixth step 312, as the plurality of dies or packages 102, which are in an array pattern the same or similar to that as shown and discussed earlier herein with respect to FIGS. 1A-1D, are removed from the support material, the plurality of dies or packages 102 are deposited onto the third side 240 of the second shelf 212 within the safe zone 256. As successive respective dies and packages 102 of the plurality of dies or packages 102 are removed from the support material 104, the plurality of dies or packages 102 push against respective dies or packages 102 previously removed from the support material 104 until an array of the plurality of dies or packages 102 are present on the third side 240 of the second shelf 212 within the safe zone 256. This array of the plurality of dies or packages 102 removed from support material 104, on the third side 240 of the second shelf 212, and within the safe zone 256 may be readily seen in FIG. 4D of the present disclosure. As shown in FIG. 4D, the plurality of dies or packages 102 organized in the array may abut each other within the safe zone 256 once removed from the support material 104.

In the seventh step 314, the support material 104 wraps up along an external surface of the second roller 244. The results of the support material 104 wrapping up along the external surface of the second roller 244 may be readily seen in FIG. 4B of the present disclosure.

Once the plurality of dies or packages 102 are fully removed from the support material 104 as shown in FIG. 4C, the plurality of dies or packages 102 may be transported to another region within the FAB to be further processed or refined. Alternatively, after the plurality of dies or packages 102 are removed from the support material 104, the plurality of dies or packages 102 may be shipped and sold to customers if no further processing or refining is to occur.

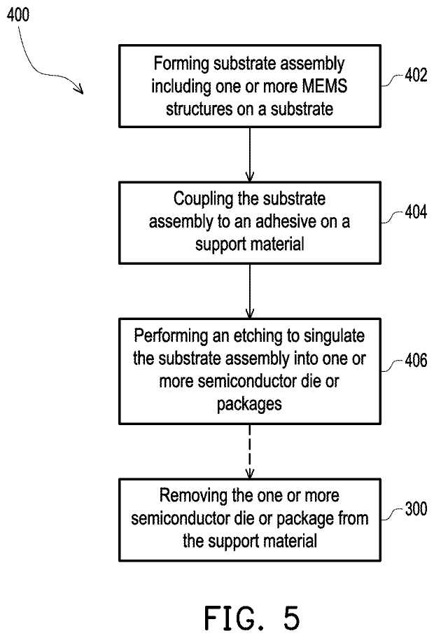

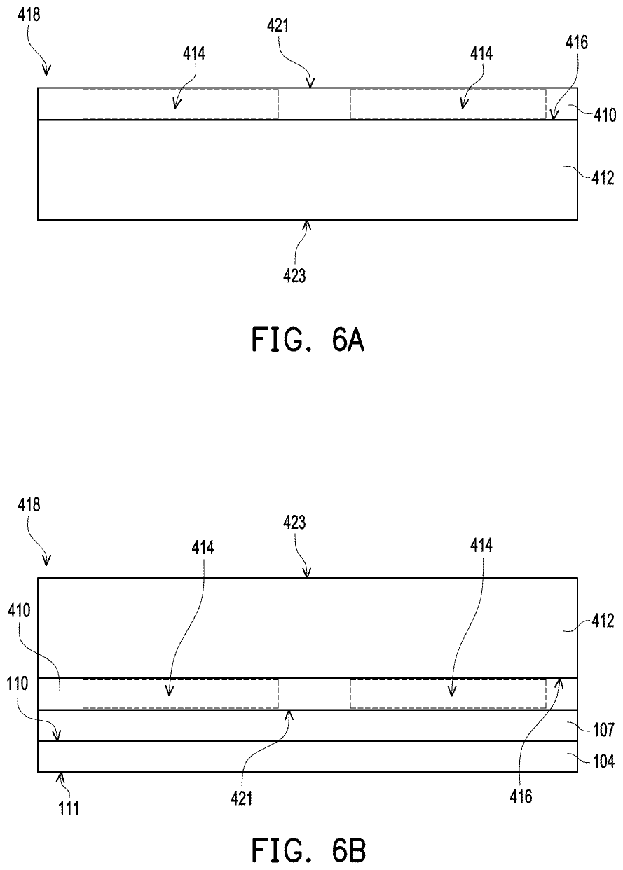

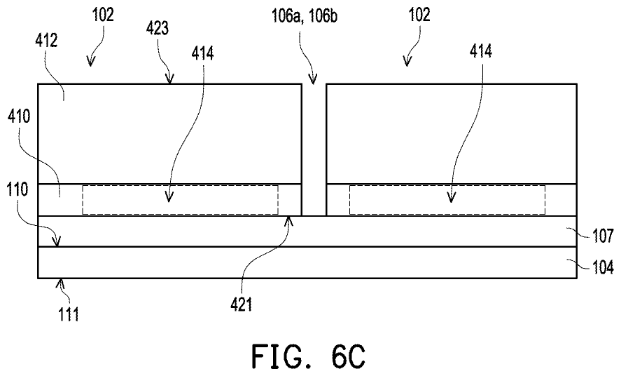

FIG. 5 is a flowchart 400 of a method of manufacturing the one or more semiconductor die or packages 102 that include a MEMS structure. The flowchart 400 includes a first step 402 (see FIG. 6A), a second step 404 (see FIG. 6B), and a third step 406 (see FIG. 6C). FIG. 6A is a cross-sectional view of the first step 402 of the method of manufacturing the MEMS structure and device as shown in the flowchart 400 of FIG. 5. FIG. 6B is a cross-sectional view of the second step 404 of the method of manufacturing the MEMS structure and device as shown in the flowchart 400 of FIG. 5. FIG. 6C is a cross-sectional view of the third step 406 of the method of manufacturing the MEMS structure and device as shown in flowchart 400 of FIG. 5.

In the first step 402 as shown in FIG. 6A, one or more conductive and non-conductive layers 410 are formed on a substrate 412. In forming the one or more conductive and non-conductive layers 410, one or more MEMS structures 414 are formed. The one or more MEMS structures 414 may include cantilevers, membranes, or some other similar or like type of MEMS structure that may be formed within the one or more conductive and non-conductive layers 410. The MEMS structures 414 formed within the one or more conductive or non-conductive layers 410 are represented by dotted rectangles. Once the one or more conductive and non-conductive layers 410 are formed on a surface 416 of the substrate 412, a substrate assembly 418 has been formed including the substrate 412, the one or more conductive and non-conductive layers 410, and the one or more MEMS structures 414 within the one or more conductive and non-conductive layers 410. The substrate assembly 418 includes a first surface 421 and a second surface 423 opposite to the first surface 421. After the first step 402 as shown in FIG. 6A, in the second step 404 as shown FIG. 6B the one or more conductive and non-conductive layers 410 are coupled to the glue layer or adhesive 107 such that the first surface 421 of the substrate assembly 418 is coupled to the support material 104 by the glue layer or adhesive 107. After the second step 404 as shown in FIG. 6B, in a third step 406 as shown in FIG. 6C an etching to singulate the substrate assembly 418 into individual and singulated ones of the one or more semiconductor die or packages 102. This etching may be a wet etching. When the etching is a wet etching, the glue layer or adhesive 107 is resistant against one or more chemicals utilized to etch the substrate assembly 418. After the wet etching is performed in the third step 406 as shown in FIG. 6C, the first channels 106a and the second channels 106b are formed such that the one or more semiconductor die and packages 102 have been formed and remain attached to the glue layer or adhesive 107. In other words, after the wet etching is performed, the one or more semiconductor die or packages 102 are organized in the pattern as shown in FIG. 1 as discussed earlier herein within the present disclosure. The results of the first channels 106a and the second channels 106b may be seen in FIG. 6C and FIG. 1. After the third step 406, the one or more semiconductor die or packages 102 are removed from the glue layer or adhesive 107 by utilizing the removal tool 200 to perform the method of the flowchart 300 as discussed in detail earlier herein within the present disclosure.

As will become readily apparent from the discussion above and herein, the present disclosure is directed to one or more embodiments of the tool 100 configured to, in operation, remove the one or more semiconductor die or packages 102 from the support material 104. The semiconductor die or packages 102 may include micro-electromechanical systems (MEMS) that include microscopic components that are susceptible to damage and defects when exposed to relatively large external stresses and strains. The tool 100 is automated to remove the one or more semiconductor die or packages 102 from the support material 104 to improve efficiency of the semiconductor manufacturing plant (FAB) by increasing the units (e.g., semiconductor die) per hour (UPH) that may be removed from the support material 104 by replacing a manual operation performed by the employee. The tool 100 is automated to replace this manual removal of the one or more semiconductor die or packages 102 from the support material 104 improving UPH (units per hour) of the FAB by decreasing a number of defects (e.g., remaining adhesive on the one or more semiconductor dies or packages 102, cracking within the one or more semiconductor dies or packages 102, delamination between layers of the one or more semiconductor dies or packages 102, or some other similar or like types of defects that may occur due to a manual operation being performed by an employee). In other words, the removal of the one or more semiconductor dies or packages 102 increases a speed of which the semiconductor dies or packages 102 may be removed from the support material 104 while at the same time improving reliability in removing the semiconductor dies or packages 102 from the support material 104. This improved speed and improved reliability increases profitability by the FAB as the UPH is increased.

At least one embodiment of a device of the present disclosure may be summarized as including: a shelf structure including: a first shelf portion; a second shelf portion spaced apart from the first shelf portion; a gap between the first shelf portion and the second shelf portion; a first side with respect to the first and second shelf portions; and a second side with respect to the first and second shelf portions, the second side being opposite to the first side; a support structure on the first shelf portion and on the first side; a first roller coupled to the support structure, the first roller is coupled to the support structure to freely rotate about the support structure, and the first roller overlaps the first shelf portion; a second roller on the second side; and a driving structure on the second side, the driving structure is in mechanical cooperation with the second roller.

At least one embodiment of a method of the present disclosure may be summarized as including: moving a carrier to which one or more semiconductor die are coupled utilizing a first roller, moving the carrier including: moving the carrier through a gap along a carrier pathway, the gap being between a first shelf portion of a shelf structure and a second shelf portion of the shelf structure; applying a first force to the one or more semiconductor die with a second roller; removing the one or more semiconductor die from the carrier; and positioning the one or more semiconductor die removed from the carrier on the second shelf portion of the shelf structure.

At least one embodiment of a device of the present disclosure may be summarized as including: a shelf structure including: a first shelf portion; a second shelf portion spaced apart from the first shelf portion; a gap between the first shelf portion and the second shelf portion; a first side with respect to the first and second shelf portions; and a second side with respect to the first and second shelf portions, the second side being opposite to the first side; a support structure on the first shelf portion and on the first side; a first roller coupled to the support structure, the first roller is coupled to the support structure to freely rotate about the support structure, and the first roller overlaps the first shelf portion; a second roller on the second side, the second roller is overlapped by first shelf portion, the second shelf portion, and the gap; and a driving structure on the second side, the driving structure is in mechanical cooperation with the second roller.

At least one embodiment of a method of the present disclosure may be summarized as including: forming a substrate assembly by forming one or more MEMS structures on a substrate; coupling a first surface of the substrate assembly at which the one or more MEMS structures are in close proximity to an adhesive on a carrier; etching a second surface of the substrate assembly opposite to the first surface forming one or more channels extending through the substrate assembly to the adhesive and defining one or more singulated semiconductor components; and removing the one or more singulated semiconductor components from the adhesive on the carrier by moving the carrier to which one or more semiconductor components are coupled utilizing a first roller of a removal tool, moving the carrier including: moving the carrier through a gap along a carrier pathway of the removal tool, the gap being between a first shelf portion of a shelf structure of the removal tool and a second shelf portion of the shelf structure of the removal tool; applying a first force to the one or more semiconductor components with a second roller of the removal tool; removing the one or more semiconductor components from the carrier by overcoming an attachment force of the adhesive; and positioning the one or more semiconductor components removed from the carrier on the second shelf portion of the shelf structure of the removal tool.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a shelf structure including:
a first shelf portion;
a second shelf portion spaced apart from the first shelf portion;
a gap between the first shelf portion and the second shelf portion;
a first side with respect to the first and second shelf portions; and
a second side with respect to the first and second shelf portions, the second side being opposite to the first side;
a support structure on the first shelf portion and on the first side;
a first roller coupled to the support structure, the first roller is coupled to the support structure to freely rotate about the support structure, and the first roller overlaps the first shelf portion;
a second roller on the second side; and
a driving structure on the second side, the driving structure is in mechanical cooperation with the second roller.

2. The device of claim 1, wherein:
the support structure includes one or more openings; and
the first roller includes one or more protrusions inserted into the one or more openings.

3. The device of claim 2, wherein the one or more openings and the one or more protrusions define a free axis of rotation about which the first roller freely rotates.

4. The device of claim 1, further comprising a guide structure coupled to the support structure.

5. The device of claim 4, wherein the first roller is downstream the guide structure along a tape and semiconductor die pathway.

6. The device of claim 1, further comprising a controller configured to, in operation, control the driving structure.

7. The device of claim 1, wherein the gap has a first dimension extending form the first shelf portion to the second shelf portion, and the first dimension is less than a second dimension of a semiconductor die or package extending between opposite sidewalls of the semiconductor die or package.

8. The device of claim 1, wherein the second shelf portion is offset from the second shelf portion.

9. The device of claim 1, wherein:
the first shelf portion includes a first surface, and, in operation, a tape is moved along the first surface; and
the second shelf portion includes a second surface offset from the first surface, and, in operation, one or more semiconductor die removed from the tape are positioned along the second surface.

10. The device of claim 9, wherein, in operation, the tape moves through the gap and is wrapped up along an external surface of the second roller.

11. A method, comprising:
moving a carrier to which one or more semiconductor die are coupled utilizing a first roller, moving the carrier including:
moving the carrier through a gap along a carrier pathway, the gap being between a first shelf portion of a shelf structure and a second shelf portion of the shelf structure;
applying a first force to the one or more semiconductor die with a second roller;
removing the one or more semiconductor die from the carrier; and
positioning the one or more semiconductor die removed from the carrier on the second shelf portion of the shelf structure.

12. The method of claim 11, wherein the carrier is a tape including an adhesive and the carrier pathway is a tape pathway.

13. The method of claim 11, further comprising positioning the carrier between a guide structure and the first shelf portion of the shelf structure and between the second roller and the first shelf portion.

14. The method of claim 11, wherein moving the carrier to which the one or more semiconductor die are coupled utilizing the first roller further includes driving the first roller with a driving structure in mechanical cooperation with the first roller.

15. The method of claim 11, wherein the applying the first force to the one or more semiconductor die with the second roller further includes freely rotating the second roller about a free axis of rotation of the second roller.

16. The method of claim 11, wherein removing the one or more semiconductor die from the carrier further includes applying a second force to the one or more semiconductor die with the second shelf portion of the shelf structure.

17. The method of claim 16, wherein the second shelf portion of the shelf structure is offset from the first shelf portion of the shelf structure.

18. A method, comprising:
forming a substrate assembly by forming one or more MEMS structures on a substrate;
coupling a first surface of the substrate assembly at which the one or more MEMS structures are in close proximity to an adhesive on a carrier;
etching a second surface of the substrate assembly opposite to the first surface forming one or more channels extending through the substrate assembly to the adhesive and defining one or more singulated semiconductor components; and
removing the one or more singulated semiconductor components from the adhesive on the carrier by moving the carrier to which one or more semiconductor components are coupled utilizing a first roller of a removal tool, moving the carrier including:
moving the carrier through a gap along a carrier pathway of the removal tool, the gap being between a first shelf portion of a shelf structure of the removal tool and a second shelf portion of the shelf structure of the removal tool;
applying a first force to the one or more semiconductor components with a second roller of the removal tool;
removing the one or more semiconductor components from the carrier by overcoming an attachment force of the adhesive; and
positioning the one or more semiconductor components removed from the carrier on the second shelf portion of the shelf structure of the removal tool.

19. The method of claim 18, wherein the etching of the second surface of the substrate assembly is a wet etching.

20. The method of claim 18, the applying the first force to the one or more semiconductor die with the second roller further includes freely rotating the second roller about a free axis of rotation of the second roller.
